(19) United States
(12) Patent Application Publication
(10) Pub. No.: US 2025/0372953 A1
(43) Pub. Date: Dec. 4, 2025

(54) VERTICAL-CAVITY SURFACE EMITTING LASER DEVICE AND METHOD OF MAKING THE SAME

(71) Applicant: QUANZHOU SANAN OPTICAL COMMUNICATION TECHNOLOGY CO., LTD., Quanzhou City (CN)

(72) Inventors: Pohan CHEN, Xiamen City (CN); Guangzheng ZHOU, Quanzhou City (CN); Liangcai JING, Quanzhou City (CN)

(21) Appl. No.: 19/197,512

(22) Filed: May 2, 2025

(30) Foreign Application Priority Data
May 31, 2024 (CN) 202410708576.7

(51) Int. Cl. H01S 5/183

(52) U.S. Cl. CPC H01S 5/18358; H01S 5/18377

(57) ABSTRACT

A VCSEL device includes a resonator cavity, an upper DBR structure and a lower DBR structure respectively located on opposite sides of the resonator cavity. Each of the upper DBR structure and the lower DBR structure has a plurality of DBR pairs that are formed from a first material layer and a second material layer. One of the upper DBR structure and the lower DBR structure has an optical phase shift layer inserted between two DBR pairs. The optical phase shift layer has a thickness of (2Nλ/4)+(1/4×Kλ), where N is a positive integer, K ranges from 0.8 to 1.2, and λ is a wavelength of a light emitted by the VCSEL device. A method of making the VCSEL device is included.

### CROSS-REFERENCE TO RELATED APPLICATION

This application claims priority to Chinese Invention patent application No. 202410708576.7, filed on May 31, 2024, the entire disclosure of which is incorporated by reference herein.

### FIELD

The disclosure relates to a VCSEL device, and more particularly to a VCSEL device and a method of making the VCSEL device.

### BACKGROUND

Vertical-cavity surface-emitting lasers (VCSEL) have advantages such as low cost, low threshold voltage, high speed and low power cost, and has been widely applied in industries such as optical communication, optical interconnection, optical storage etc. A VCSEL is composed of a resonator cavity and two distributed Bragg reflectors (DBR) respectively located above and below the resonator cavity, and has a light exiting surface that is perpendicular to the resonator cavity. The conventional VCSEL has an optical intensity distribution that is most intense around the resonator cavity and gradually decreasing in proportion to distance away from the resonator cavity.

The optical intensity distribution of the conventional VCSEL often causes design difficulties due to practical considerations. For example, a current confinement layer of the conventional VCSEL might cause optical diffraction, thereby creating an overly large divergence angle. This is especially important optical communications and optical sensors that require a smaller divergence angle. In these circumstances an overly large divergence angle will complicate design considerations when adapting the conventional VCSEL for practical applications. For example, when applying the conventional VCSEL for 3D sensors and light detection and ranging (lidar), the optical intensity distribution of the conventional VCSEL will need to be adjusted and optimized to enhance detection distance, resolution, and signal-to-noise ratio. However, when the divergence angle of the conventional VCSEL is too large the optimization of the optical intensity distribution becomes more difficult. In order to solve this problem some conventional VCSELs may expand the resonator cavity so that the light field shifts to the DBR below the resonator cavity. In general, although this type of structure will successfully suppress the divergence angle, there is an accompanied loss of light emission efficiency. Furthermore, because the resonator cavity is expanded and thicker, epitaxial growth thereof will necessarily be slower and costlier. Furthermore, in this case, the peak optical intensity of the conventional VCSEL will be in the resonator cavity and overlap with a light emitting layer, this causes aging and reduces the service life and reliability of the conventional VCSEL.

### SUMMARY

Therefore, an object of the disclosure is to provide a vertical-cavity surface-emitting laser (VCSEL) device and a method of making the VCSEL device that can alleviate at least one of the drawbacks of the prior art.

According to a first aspect of the disclosure, the vertical-cavity surface-emitting laser (VCSEL) device includes a resonator cavity, an upper distributed Bragg reflector (DBR) structure, and a lower DBR structure. The upper distributed Bragg reflector structure is located on one side of the resonator cavity. The lower DBR structure is located on an opposite side of the resonator cavity. Each of the upper DBR structure and the lower DBR structure has a plurality DBR pairs that are each formed from a first material layer with a low refractive index and a second material layer with a higher refractive index. One of the upper DBR structure and the lower DBR structure has at least one optical phase shift layer inserted between two adjacent ones of the DBR pairs. The at least one optical phase shift layer has a thickness of (2Nλ/4)+(1/4×Kλ), where N is a positive integer, K ranges from 0.8 to 1.2, and λ is a wavelength of a light emitted by the VCSEL device. The first material layer has a refractive index of η₁, the second material layer has a refractive index of η₂, and the at least one optical phase shift layer has a refractive index of η, and 0.8η₁≤η≤1.2η₁ or 0.8η₂≤η≤1.2η₂.

According to another aspect of the disclosure, the method of making the VCSEL device as disclosed above includes the steps of: a) epitaxially, forming a lower DBR structure, a resonator cavity, and an upper DBR structure sequentially so that the upper DBR structure and the lower DBR structure are formed on opposite sides of the resonator cavity. Each of the upper DBR structure and the lower DBR structure has a plurality of DBR pairs that are each epitaxially formed by alternatingly growing a first material layer with a low refractive index and a second material layer with a high refractive index repeatedly; n) forming a current channel in proximity to the resonator cavity or inside the resonator cavity; c) inserting at least one optical phase shift layer in at least one of the upper DBR structure and the lower DBR structure to adjust a peak optical intensity of the VCSEL device to shift outside of the resonator cavity. The at least one optical phase shift layer has a thickness of (2Nλ/4)+(1/4×Kλ), where N is a positive integer, K ranges from 0.8 to 1.2, and λ is a wavelength of a light emitted by the VCSEL device, wherein the first material layer has a refractive index of η₁, the second material layer has a refractive index of η₂, and the at least one optical phase shift layer has a refractive index of η, and 0.8η₁≤η≤1.2η₁ or 0.8η₂≤n≤1.2η₂.

According to still another aspect of the disclosure, a VCSEL chip includes a plurality of the above disclosed VCSEL devices that are arranged in an array or randomly distributed on the VCSEL chip.

According to still yet another aspect of the disclosure, a lidar system includes at least one of the previously disclosed VCSEL chip or VCSEL device.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a first embodiment of a vertical-cavity surface-emitting laser (VCSEL) device according to the disclosure.

FIGS. 2A to 2C are fragmentary schematic cross-sectional views illustrating different examples of an upper DBR structure of the VCSEL device of the first embodiment, wherein two optical phase shift layers have the same thickness in FIG. 2B and different thicknesses in FIG. 2C.

FIGS. 3A to 3D are diagrams illustrating refractive index characteristics of the first embodiment.

FIG. 3E is a diagram illustrating refractive index characteristics of a conventional VCSEL device.

FIG. 4 is a schematic cross-sectional view illustrating a modified variation of the first embodiment.

FIG. 5 is a diagram illustrating optical intensity distribution characteristics of a conventional VCSEL device.

FIG. 6A is a power over current diagram showing relation between input current and output power of the example of the first embodiment shown in FIGS. 2B and 3A.

FIG. 6B is a refractive index over distance diagram showing refractive indices at or near a resonator cavity of FIGS. 2B and 3A.

FIG. 6C is an optical intensity distribution cross-section diagram of the example of FIGS. 2B and 3A.

FIG. 6D is an optical intensity distribution diagram of the interior of the VCSEL device of FIGS. 2A and 3B.

FIGS. 7A to 7D respectively show a power over current diagram, a refractive index over distance diagram, an optical intensity distribution cross-section diagram, and an optical intensity distribution diagram for the example shown in FIGS. 2B and 3B.

FIG. 8 is a fragmentary schematic cross-sectional view illustrating a lower DRB structure of a second embodiment of a VCSEL device according to the present disclosure.

FIGS. 9A and 9B are diagrams illustrating refractive index characteristics of two examples of the VCSEL device of the second embodiment.

FIGS. 10A to 10D show a power over current diagram, a refractive index over distance diagram, an optical intensity distribution cross-section diagram, and an optical intensity distribution diagram for the example shown in FIGS. 8 and 9A.

FIGS. 11A to 11D show a power over current diagram, a refractive index over distance diagram, an optical intensity distribution cross-section diagram, and an optical intensity distribution diagram for the example shown in FIGS. 8 and 9B. FIG. 11B is a refractive index over distance diagram covering a resonator cavity of the second embodiment.

FIG. 12 is a fragmentary schematic cross-sectional view illustrating a third embodiment of the VCSEL device according to the present disclosure.

FIG. 13 is a schematic cross-sectional view illustrating a fourth embodiment of the VCSEL device according to the present disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

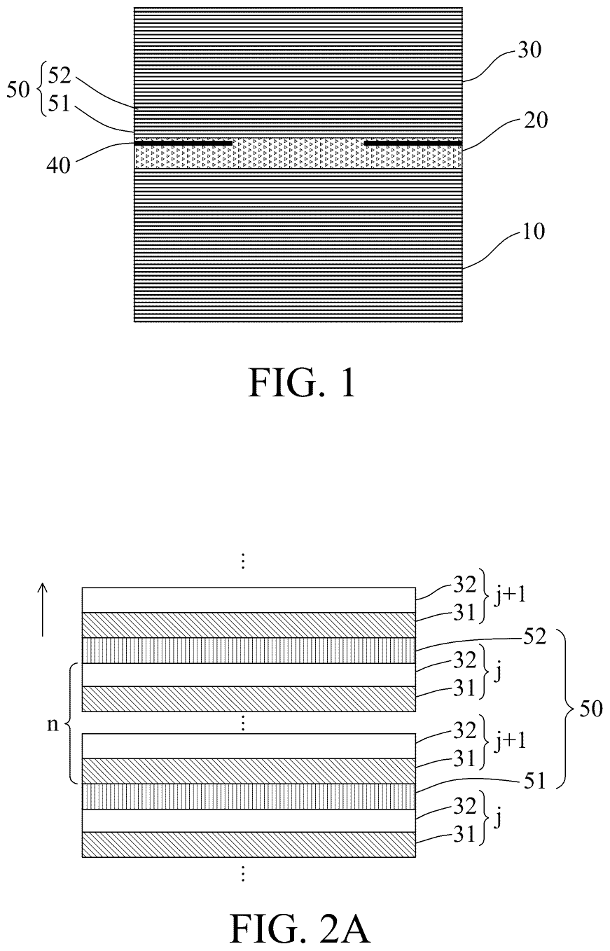

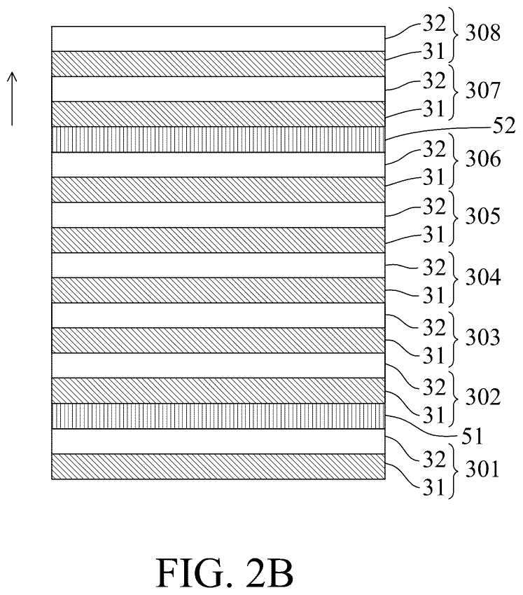

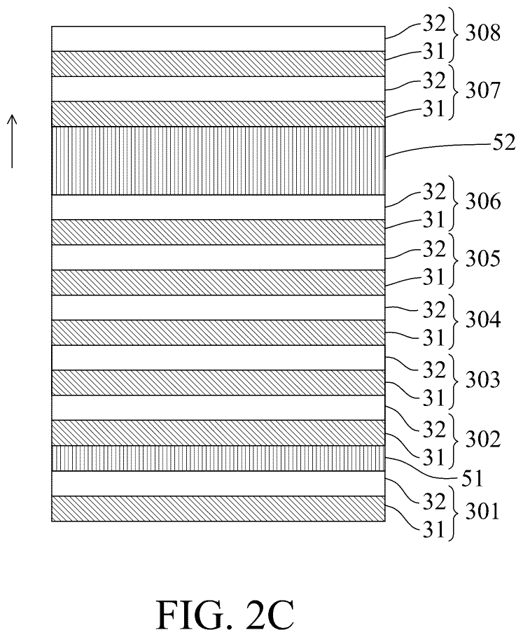

Referring to FIG. 1, a first embodiment of a vertical-cavity surface-emitting laser (VCSEL) device according to the present disclosure includes a substrate (not shown in FIG. 1), a resonator cavity 20, a lower distributed Bragg reflector (DRB) structure 10, and an upper distributed Bragg reflector (DBR) structure 30. The upper DBR structure 30 is located on one side of the resonator cavity 20, and the lower DBR structure 10 is located on an opposite side of the resonator cavity 20. Each of the upper DBR structure 30 and the lower DBR structure 10 has a plurality of DBR pairs that are each formed from a first material layer with a low refractive index and a second material layer with a high refractive index. Each of the first material layer and the second material layer has a thickness of (1/4λ λ, where λ is a wavelength of a light emitted by the VCSEL device which is equal to a material thickness that light emitted by the VCSEL device passes-through in one wave period. The VCSEL device further includes a current confinement layer 40. The current confinement layer 40 is disposed in a light-emitting area of the resonator cavity 20 that is for restricting current injection into the light emitting area, and forms an electrical channel. In some embodiments, the current confinement layer 40 may be disposed outside of the resonator cavity 20, in an area close to the resonator cavity 20. In the FIG. 2A, the arrow shows the epitaxial growth direction, and the DBR pairs of the upper DBR structure 30 are shown. Each DBR pair is formed from the first material layer 31 with the low refractive index and the second material layer 32 with the high refractive index. The first material layers 31 are alternated with the second material layers 32 along the epitaxial growth direction. One of the upper DBR structure 30 and the lower DBR structure 10 has at least one optical phase shift layer 50 inserted between two adjacent ones of the DBR pairs. The at least one optical phase shift layer 50 has a thickness of (2Nλ/4)+(1/4×Kλ), where N is a positive integer, K ranges from 0.8 to 1.2, and λ is a wavelength of a light emitted by the VCSEL device. Referring back to FIG. 2A, in this embodiment, a first optical phase shift layer 51 is inserted between an i^{th} one of the DBR pairs and in (i+1)^{th} one of the DBR pairs. The first material layers 31 with the low refractive index has a refractive index of η₁, the second material layers 32 with the high refractive index has a refractive index of η₂, and the first optical phase shift layer 51 has a refractive index of η, where 0.8η₁≤n≤1.2η₁, or 0.8η₂≤n≤1.2η₂. In other words, the first optical phase shift layer 51 may have a refractive index that is similar or the same as the refractive index of the first material layers 31 or the second material layers 32. The first optical phase shift layer 51 has a thickness of (2Nλ/4)+(1/4×Kλ), where N is a positive integer, A is a wavelength of a light emitted by the VCSEL device which is equal to a physical thickness of the material layer required for one wave period of the wavelength of light emitted by the VCSEL device to advance, and K ranges from 0.8 to 1.2. After n pairs of DBR are formed on the first optical phase shift layer 51 inserted between the i^{th} one of the DBR pairs and the (i+1)^{th} one of the DBR pairs, a second optical phase shift layer 52 is inserted between a j^{th} DBR pair and a (j+1)^{th} DBR pair. The second optical phase shift layer 52 has a thickness of (2Nλ/4)+(1/4×Kλ), where N is a positive integer, and K ranges from 0.8 to 1.2. It is noted that n DBR pairs are between the first and second optical phase layers 51 and 52, where n=j−i, and j, i, n are all positive integers and i≥1 and n≥1. In some embodiments, n may be 2, 3, 4, 5, or 6. In some embodiments, n is less than 10. In some embodiments, the first optical phase shift layer 51 and the second optical phase shift layer 52 are separated by no more than 10 of the DBR pairs of one of the upper DBR structure or the lower DBR structure 10. The second optical phase shift layer 52 may have a refractive index that is similar as or the same as the first material layer 31 or the second material layer 32. More specifically the second optical phase shift layer may have a refractive index of η, where 0.8η₁≤n≤1.2η₁, or 0.8η₂≤η≤1.2η₂. By designating K to range from 0.8 to 1.2 any optical phase shift layer (for example, the first and second optical phase shift layers) inserted between the DBR pairs may provide the best effect. By designating 0.8η₁≤η≤1.2η₁, or 0.8η₂≤η≤1.2η₂ any optical phase shift layer (for example, the first and second optical phase shift layers) may be in range of the most appropriate refractive index.

In this embodiment, the upper DBR structure 30 has the first optical phase shift layer 51, and the second optical phase shift layer 52. However, this is not a limitation of the disclosure. In other embodiments, the upper DBR structure may have two or more optical phase shift layers.

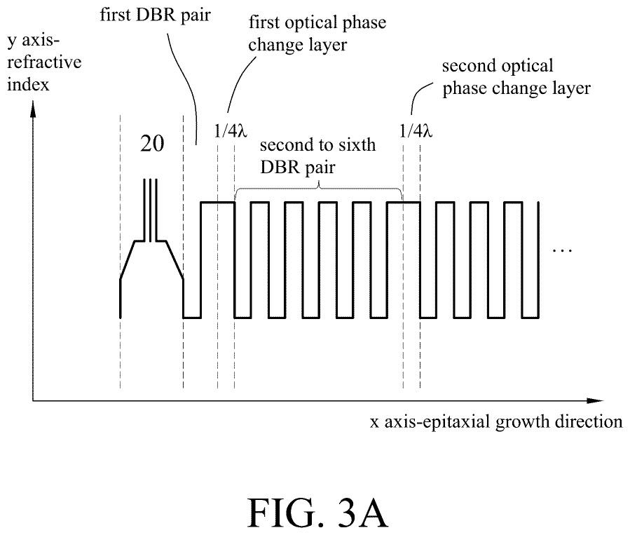

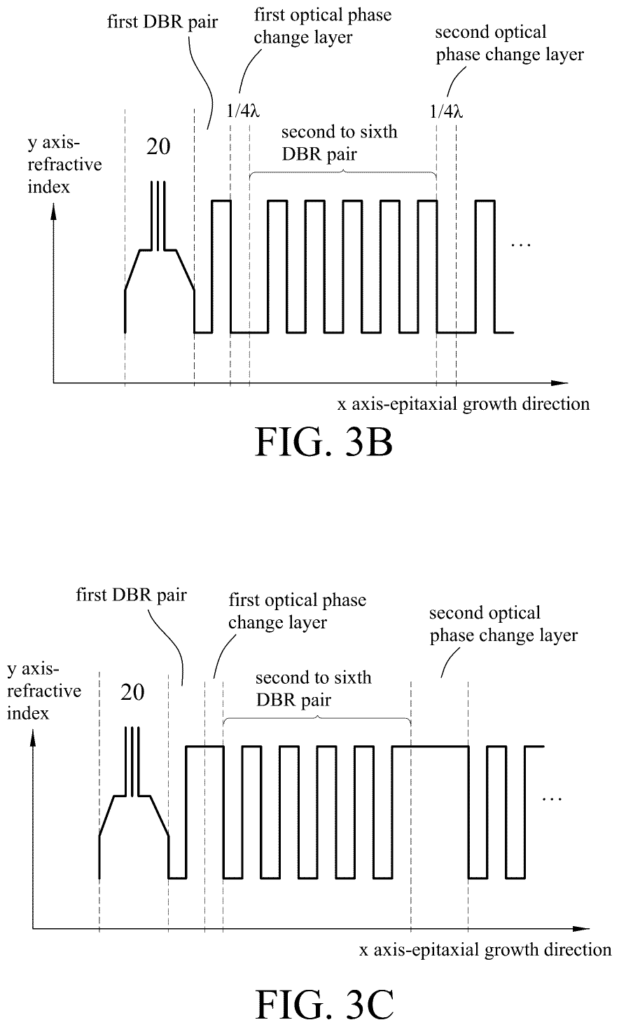

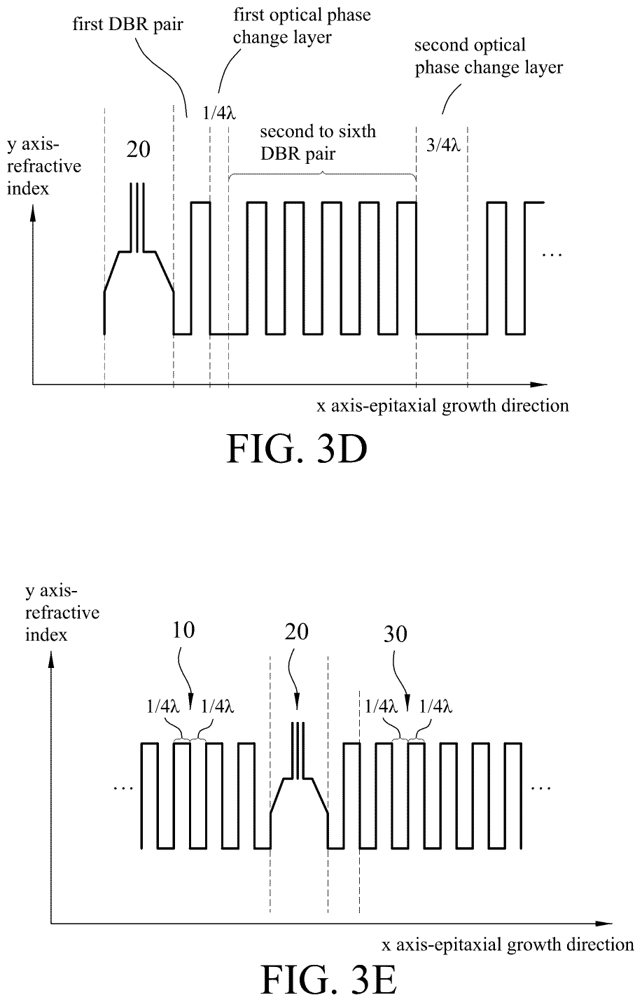

In some embodiments, such as those shown in FIGS. 2B, 3A, and 3B, the DBR pairs of the upper DBR structure 30 are numbered 301 to 308 along an epitaxial direction, and a first optical phase shift layer 51 is inserted between the first DBR pair 301 and the second DBR pair 302. A second optical phase shift layer 52 is inserted between the sixth DBR pair 306 and the seventh DBR pair 307. The first optical phase shift layer 51 and the second optical phase shift layer 52 is spaced apart and separated by five DBR pairs, that is, the second DBR pair 302, the third DBR pair 303, the fourth DBR pair 304, the fifth DBR pair 305, and the sixth DBR pair 306. The eighth DBR pair 308 is disposed on the seventh DBR pair 307. It is noted from FIG. 2B that the first optical phase shift layer 51 has a thickness of 1/4λ (N=0, K=1), the second phase shift layer 52 has a thickness of 1/4λ (N=0, K=1). Referring to FIG. 3A, the first optical phase shift layer 51 and the second optical phase shift layer 52 are made of high refractive index materials. The second optical phase shift layer 52 has a refractive index of η, where 0.8η₂≤η≤1.2η₂. For example, the second optical phase shift layer 52 may have a refractive index that is the same as the high refractive index of the second material layer 32 of the upper DBR structure 30 (n=η₂). Referring to FIG. 3B, the first optical phase shift layer 51 and the second optical phase shift layer 52 are made of materials with a low refractive index. The second optical phase shift layer 52 has a refractive index of η, where 0.8η₁≤η≤1.2η₁. For example, the second optical phase shift layer 52 may have a refractive index that is the same as the low refractive index of the first material layer 31 of the upper DBR structure 30 (η=η₁). It should be noted that, the first optical phase shift layer 51 may have a thickness that is the same as or different from the second optical phase shift layer 52. Referring to FIG. 2C, in this embodiment, the first optical phase shift layer 51 has a thickness of 1/4λ (N=0, K=1), the second optical phase shift layer 52 has a thickness of 3/4λ (N=1, K=1). Referring to FIG. 3C the first optical phase shift layer 51 has a thickness of 1/4λ, the second optical phase shift layer 52 has a thickness of 3/4λ. The first optical phase shift layer 51 and the second optical phase shift layer 52 are made of materials with a high refractive index, and both have refractive indexes that are the same as the second material layer 32 of the upper DBR structure 30. Referring to FIG. 3D, the first optical phase shift layer 51 has a thickness of 1/4λ, the second optical phase shift layer 52 has a thickness of 3/4λ. The first optical phase shift layer 51 and the second optical phase shift layer 52 are made of materials with a low refractive index, and both have refractive indexes that are the same as the first material layer 31 of the upper DBR structure 30. It should be noted that in some embodiments, the first optical phase shift layer 51 may have a thickness of 3/4λ and the second optical phase shift layer 52 may have a thickness of 1/4λ.

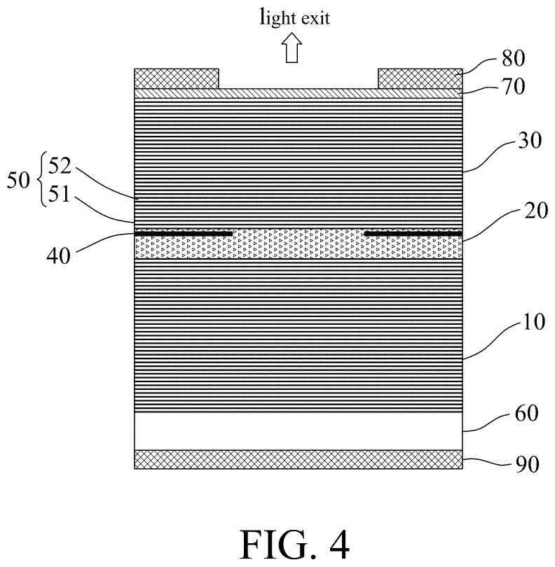

Referring to FIG. 4, in a variation of the first embodiment, the VCSEL device is a GaAs-base VCSEL, and the VCSEL device includes a substrate 60 disposed at one side of the lower DBR structure 10 opposite to the resonator cavity 20, that is to say, the lower DBR structure 10 is disposed on the substrate 60. In this embodiment, the substrate 60 is an N-type substrate and the lower DBR structure 10 is also N-type doped. The resonator cavity 20 includes a quantum well structure, and barrier layers disposed on opposite sides of the quantum well structure; the quantum well structure may be a multiple quantum well structure including multiple stacks of InGaAs/AlGaAs. The current confinement layer 40 is disposed on a side of the resonator cavity 20 that is proximate to the upper DBR layer 30. The current confinement layer 40 is made of an AlGaAs material with a high Al composition, and undergoes a wet oxidation process to form an aluminum oxide insulating area. An un-oxidized area in the middle of the current confinement layer 40 forms a conductive channel that enables effective current injection. The upper DBR layer 30 is a P-type DBR and has a P-type contact layer 70, and a P-type annular electrode 80 disposed on the P-type contact layer 70. The VCSEL device has a light exiting surface on a side of the upper DBR structure 30 that is remote from the resonator cavity 20. More specifically, an inner rim of the P-type annular electrode 80 forms a light exiting surface on the P-type contact layer 70. The substrate 60 has an N-type electrode 90 disposed on a surface that is away from the lower DBR structure 10. The upper DBR structure 30 and the lower DBR structure are each AlGaAs-based DBR structures. In this embodiment, the first material layer 11, 31 with the low refractive index is made of Al_{0.85}Ga_{0.15}As, the second material layer 12, 32 with the high refractive index is made of Al_{0.12}Ga_{0.88}As, and a reflectance of the lower DBR structure 10 is higher than a reflectance of the upper DBR structure 30 which means that light emitted by the VCSEL device will exit from the side of the upper DBR structure 30. Additionally, according to the wavelength requirements for the light emitted by the VCSEL device, the upper DBR structure 30 and the lower DBR structure 10 may be made of AlGaAs combined with another material, or AlInN/GaN, SiO₂/Nb₂O₅, or SiO₂/Ta₂O₅. In some embodiments, the first and second materials are AlₓGa₁₋ₓAs/Al_{y}Ga_{1-y}As, AlInN/GaN, SiO₂/Nb₂O₅, and AlGalnAs/InP or SiO₂/Ta₂O₅, where 1>x>y>0.

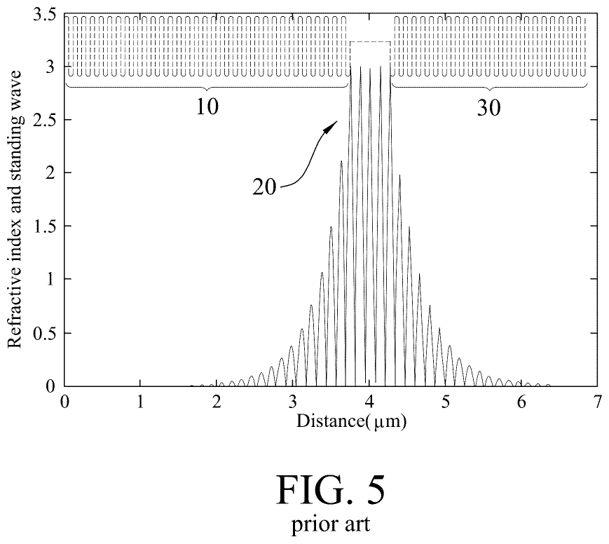

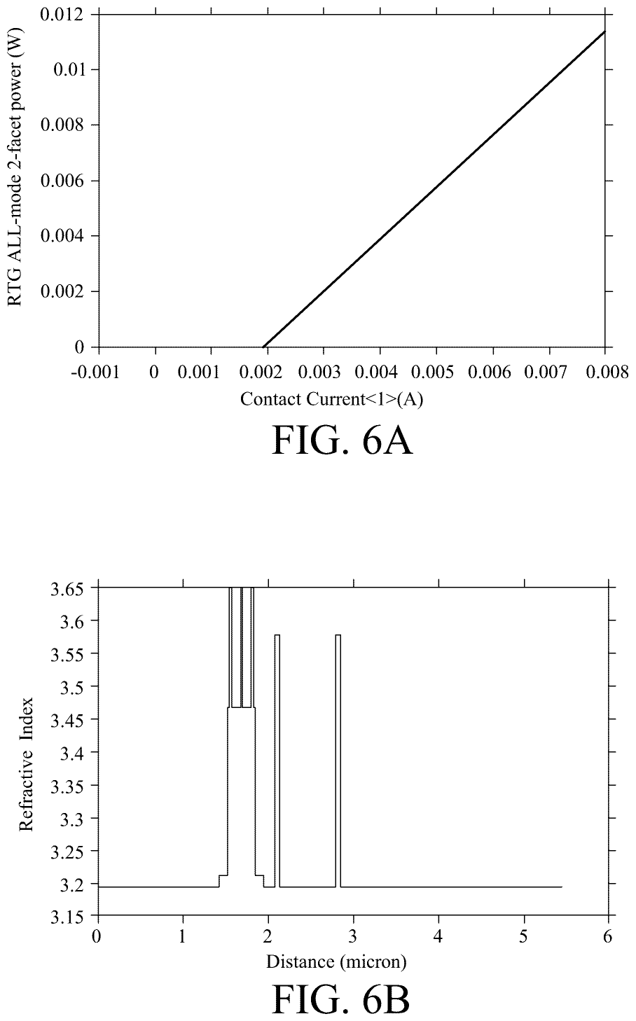

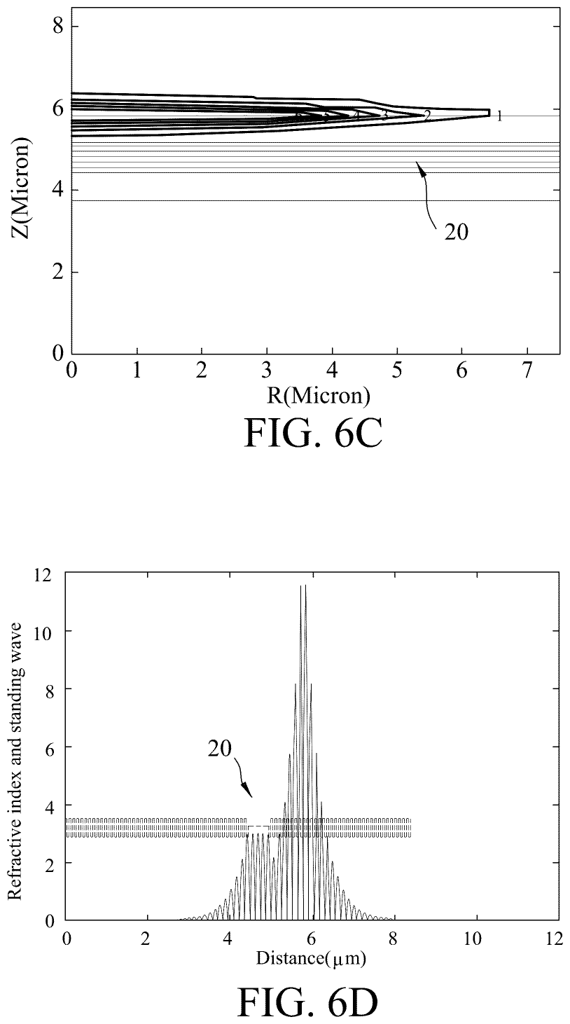

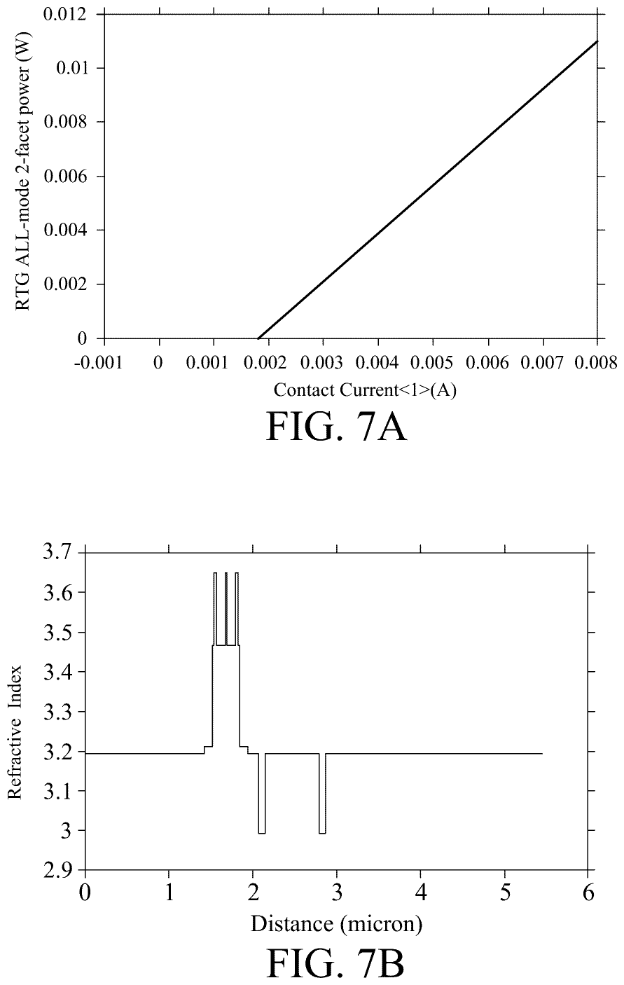

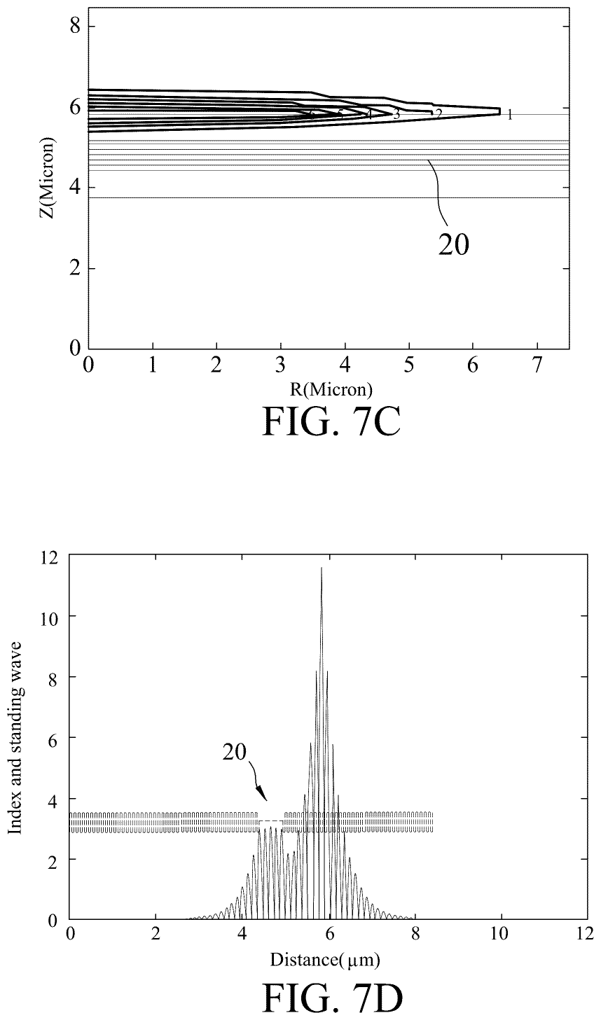

Referring to FIG. 3E, a DBR structure of a conventional VCSEL device is made of layers of a high refractive index material having a thickness of 1/4λ (a quarter wavelength of the target wavelength, which is the wavelength of a light that is expected to pass through the DBR structure) alternatingly stacked with layers of a low refractive index material with a thickness of 1/4λ. When the light passes through the layers with different refractive indexes, the reflected light rays from different layers generate constructive interferences and combine each other to achieve a high reflectivity. Referring to FIG. 5, in the conventional VCSEL device, optical intensity is distributed around the resonator cavity 20 as a center. In other words, a peak optical intensity will be located in the resonator cavity 20, and the current confinement layer 40 will be located at a center of the peak optical intensity; this results in emission of light with an overly large beam divergence due to diffraction. Referring to FIGS. 3A and FIGS. 6A to 6D, in this embodiment, two optical phase shift layers each with a thickness of 1/4λ and a higher refractive index are inserted between two adjacent DBR pairs of the upper DBR structure 30. FIG. 6A is a power over current diagram showing relation between input current and output power of the VCSEL device. FIG. 6B is a refractive index over distance diagram showing refractive indices at and near the resonator cavity 20, wherein two projections indicate locations of two phase shifts of high refractive index. FIG. 6C is an optical intensity distribution cross-section diagram, wherein the central dense horizontal lines are offset from the quantum well structure of the resonator cavity 20. FIG. 6D is an optical intensity distribution diagram of the interior of the VCSEL device. From a computer model simulation that was conducted on the VCSEL device (as shown in FIG. 6D), it was observed that the optical intensity distribution changes dramatically in the VCSEL device; peak optical intensity of the VCSEL device is shifted to a region between the two locations of high refractive index phase shifts. This means that the interaction between the light emitted by the VCSEL device and structures around the resonator cavity 20 may be reduced, thereby effectively avoiding diffraction caused by the current confinement layer, and reducing beam divergence without lowering optical intensity. In this way a higher output may be achieved. Referring to FIG. 3B and FIG. 7A to FIG. 7D, in this embodiment, two optical phase shift layers each with a thickness of 1/4λ and a low refractive index are inserted in the upper DBR structure 30. FIG. 7A is a power over current diagram showing relation between input current and output power of the VCSEL device. FIG. 7B is a refractive index over distance diagram showing the refractive index over an area covering the resonator cavity 20, wherein two downward recesses indicate locations of two phase shifts of low refractive index. FIG. 7C is an optical intensity distribution cross-section diagram, which shows that the area of multiple middle dense horizontal lines are offset from the structure of the resonator cavity 20. FIG. 7D is an optical intensity distribution diagram of the interior of the VCSEL device. The two optical phase shift layer with the low refractive index inserted in the upper DBR structure 30 in this example of the first embodiment may have the advantage of adjusting optical intensity distribution by shifting the peak optical intensity out of the resonator cavity, like the examples described hereinbefore. Moreover the extent of overlap between the peak optical intensity region and the resonator may be reduced to enhance reliability of the VCSEL device.

A method of making an embodiment of the VCSEL device includes the steps a) to c). It should be noted that additional steps can be provided before, during or after the method, and some of the steps described herein may be replaced by other steps or be eliminated. Similarly, further additional features may be present in the semiconductor structures, and/or features present may be replaced or eliminated in additional embodiments. In the step a), a lower DBR structure 10, a resonator cavity 20, and an upper DBR structure 30 are epitaxially formed sequentially so that the upper DBR structure 30 and the lower DBR structure 10 are formed on opposite sides of the resonator cavity 20. More specifically, in some embodiments, the lower DBR structure 10, the resonator cavity 20, and the upper DBR structure 30 may be sequentially formed epitaxially on a substrate 60, and afterwards a P-type contact layer 70 may be formed on the upper DBR structure 30. Each of the upper DBR structure 30 and the lower DBR structure 10 has a plurality of DBR pairs that are each epitaxially formed by alternatingly growing a first material layer 11, 31 with a low refractive index and a second material layer 12, 32 with a high refractive index repeatedly.

Next, in the step b) a current confinement layer 40 is formed in proximity to the resonator cavity 20 or inside the resonator cavity 20. Afterwards, in the step c) at least one optical phase shift layer 50 is inserted in at least one of the upper DBR structure 30 and the lower DBR structure to adjust a peak optical intensity of the VCSEL device to shift outside of the resonator cavity 20. The at least one optical phase shift layer 50 has a thickness of (2Nλ/4)+(1/4×Kλ), where N is a positive integer, K ranges from 0.8 to 1.2, and λ is a wavelength of a light emitted by said VCSEL device, wherein the first material layer 11, 31 has a refractive index of η₁, the second material layer 12, 32 has a refractive index of η₂, and the at least one optical phase shift layer 50 has a refractive index of η, and 0.8η₁≤η≤1.2η₁ or 0.8η₂≤η≤1.2η₂.

In the step of epitaxially forming the upper DBR structure 30 and the lower DBR structure 10, a growth thickness of the first material layer 11, 31 or the second material layer 12, 32 may be increased to form the at least one optical phase shift layer 50. More specifically, the optical phase shift layer 50 is inserted during alternatingly growing the first material layer 11, 31 with the low refractive index and the second material layer 12, 32 with the high refractive index in the upper DBR structure 30 or the lower DBR structure 10, by prolonging the growth period during growing one of the first material layers 11, 31 or the second material layers 12, 32 to increase the thickness of one of the first material layers or the second material layers by an amount equal to the thickness of (2Nλ/4)+(1/4×Kλ) of the optical phase shift layer.

Accordingly, in the embodiment of the VCSEL device made by the method, the optical phase shift layer 50 may be made of a same material as the first material layer, and the first material layer of one of two adjacent ones of the DBR pairs has an increased thickness that is increased by an amount that is equal to the thickness of (2Nλ/4)+(1/4×Kλ) of the optical phase shift layer. The optical shift layer 50 may also be made of a same material as the second material layer, and the second material layer of one of two adjacent ones of the DBR pairs has an increased thickness that is increased by an amount equal to the thickness of (2Nλ/4)+(1/4×Kλ) of the optical phase shift layer.

In this method, a current confinement layer 40 is formed via wet air oxidation to form a confining channel. Next, an N-type electrode 90 is formed on a side of the substrate 60, and a P-type electrode 80 is formed on the P-type contact layer 70. Furthermore, in some embodiments, the method of making the VCSEL device may include etching to form a mesa structure, forming a dielectric layer and other known processing which are omitted in the following. The method of making the VCSEL according to the present disclosure achieve a lower fabrication cost and is more suitable for mass production.

In one implementation of the embodiments of the present disclosure, a plurality of the VCSEL devices disclosed above are arranged in an array or randomly distributed on a chip so that the VCSEL chip includes a plurality of the VCSEL devices. In another implementation of the embodiments, at least one VCSEL device as disclosed above, or at least one VCSEL chip disclosed above is used in a lidar system. Such a lidar system may have advantages such as better beam divergence and higher optical intensity, and may thus offer higher resolution and better performance.

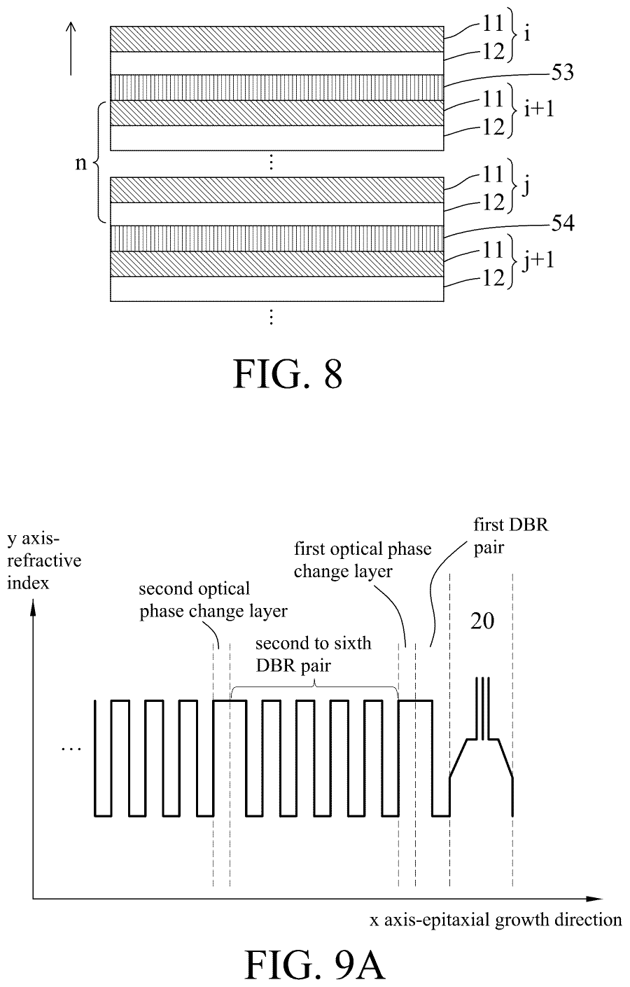

Referring to FIG. 8, a second embodiment according to the present disclosure is a VCSEL device that is similar to the first embodiment. However, the second embodiment is different from the first embodiment in that the upper DRB structure 30 is a normal DBR structure without the optical phase shift layer 50 inserted therein, and the lower DBR structure 10 has a first optical phase shift layer 53 and a second optical phase shift layer 54 inserted therein. More specifically, referring to FIG. 8, the first optical phase shift layer 53 is inserted between the i^{th} DBR pair and the i+1th DBR pair of the lower DBR structure 10, and the second optical phase shift layer 54 was inserted between the j^{th} DBR pair and the (j+1)^{th} DBR pair of the lower DBR structure 10; the second optical phase shift layer 54 is inserted after n DBR pairs are formed subsequent to formation of the first optical phase shift layer 53, where η=j−i, j, i, and n are all positive integers with i>1, n>2. In some embodiments, n may be 2, 3, 4, 5, 6 and may be lower than 10. The first optical phase shift layer 53 has a refractive index that is similar or approximate to the first material layer 11 and the second material layer 12 of the lower DBR structure 10. The first optical phase shift layer 53 may have a refractive index that ranges from 0.8 η₁ to 1.2 η₁ or from 0.8 η₂ to 1.2 η₂. The first optical phase shift layer 53 may have a thickness of (2Nλ/4)+(1/4×Kλ), where N is a positive integer, K ranges from 0.8 to 1.2, and λ is a wavelength of a light emitted by the VCSEL device which is equal to a physical thickness of the material layer required for a wave period of a wavelength of light emitted by the VCSEL device to advance. The second optical phase shift layer 54 may have a refractive index that is similar to or approximate to the first material layer 11 or the second material layer 12 of the lower DBR structure 10. The optical phase shift layer 54 has a refractive index that ranges form 0.8 η₁ to 1.2 η₁ or from 0.8 η₂ to 1.2 η₂. The second optical phase shift layer 54 may have a thickness of (2Nλ/4)+(1/4×Kλ), where N is a positive integer, K ranges from 0.8 to 1.2, and λ is a wavelength of a light emitted by the VCSEL device which is equal to a physical thickness of the material layer required for a wave period of the wavelength emitted by the VCSEL device to advance.

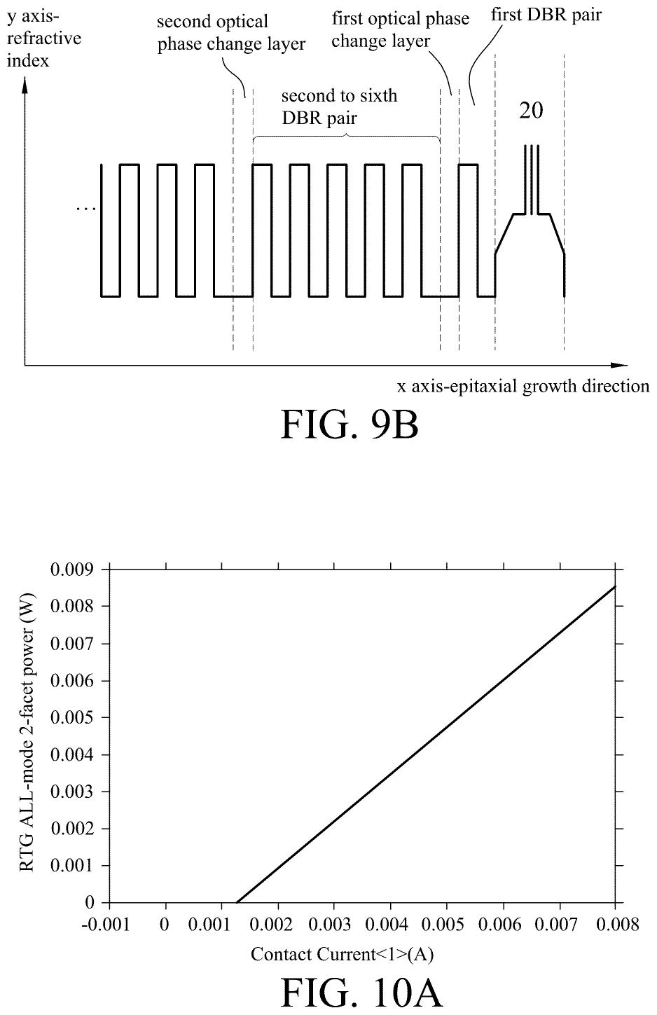

FIGS. 9A and 9B respectively showing two different embodiments. In both these embodiments, the first optical phase shift layer 53 is inserted between a first DBR pair and a second DBR pair of the lower DBR structure 10. After forming 2 to 6 DBR pairs, for example 5 pairs, subsequent to formation of the first optical phase shift layer 53, the second optical phase shift layer 54 is inserted between the sixth DBR pair and the seventh DBR pair of the lower DBR structure 10 and is segregated from the first optical phase shift layer 53 by 5 DBR pairs in the lower DBR structure. In this embodiment, the first optical phase shift layer 53 has a thickness of 1/4λ, and the second optical phase shift layer 54 has a thickness of 1/4λ. In the embodiment in FIG. 9A, the first optical phase shift layer 53 and the second optical phase shift layer 54 are each made of a material with a high refractive index and each has a refractive index that ranges from 0.8 η₂ to 1.2 η₂. For example, the first optical phase shift layer 53 and the second optical phase shift layer 54 in FIG. 9A may be made of a material that is the same as the second material layer 12 with the high refractive index. In the embodiment in FIG. 9B, the first optical phase shift layer 53 and the second optical phase shift layer 54 are each made of a material with a low refractive index and each has a refractive index that ranges from 0.8 η₁ to 1.2 η₁. For example, the first optical phase shift layer 53 and the second optical phase shift layer 54 in FIG. 9A may be made of a material that is the same as the first material layer 11 with the low refractive index. It should be noted that in these two embodiments, the first optical phase shift layer 53 and the second optical phase shift layer 54 may have thicknesses that are the same, or different from each other.

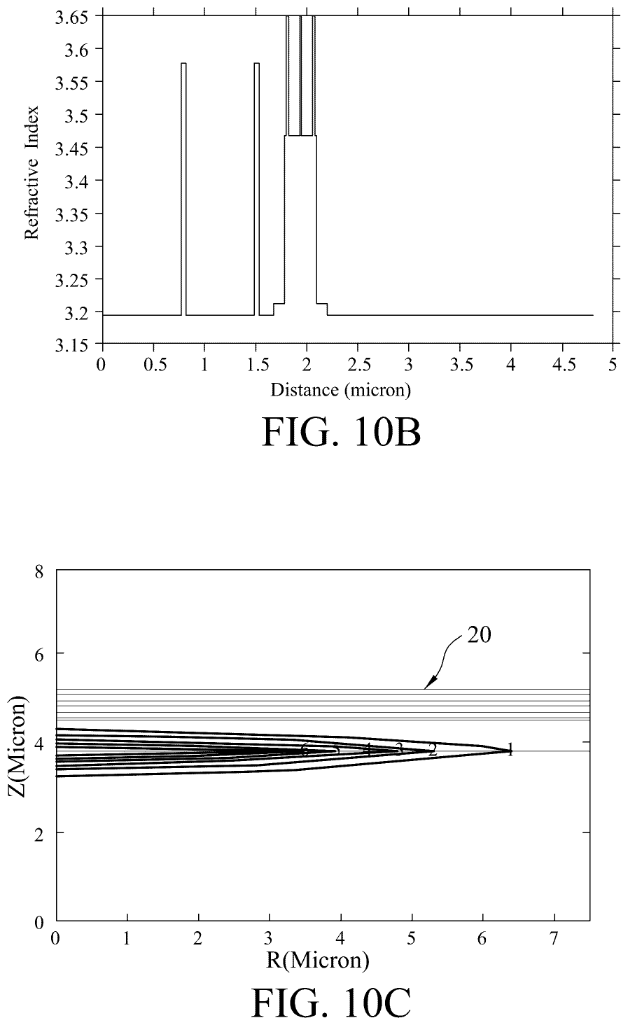

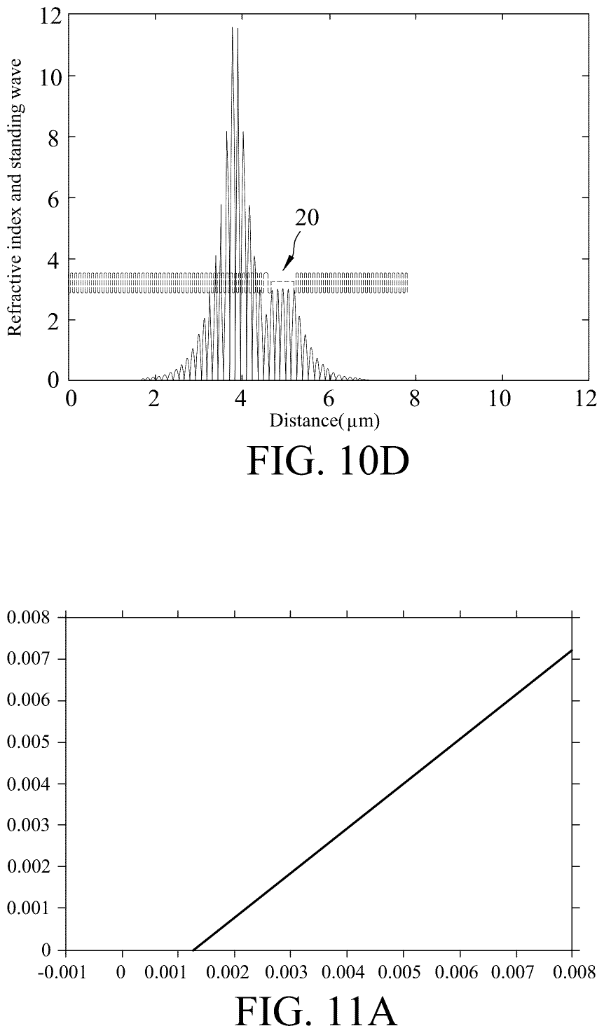

Referring to FIG. 9A and FIGS. 10A to 10D, two optical phase shift layers each with a thickness of 1/4λ and a high refractive index are inserted between two adjacent DBR pairs of the lower DBR structure 10. FIG. 10A is a power over current diagram showing relation between input current and output power of the VCSEL device. FIG. 10B is a refractive index over distance diagram showing the refractive index over an area covering the resonator cavity 20, wherein two rising projections indicate two locations of phase shifts of high refractive index. FIG. 10C is an optical intensity distribution cross-section diagram. It is noted that multiple middle dense horizontal lines are offset from the structure of the resonator cavity 20. FIG. 10D is an optical intensity distribution diagram of the interior of the VCSEL device. The two optical phase shift layer with the low refractive index inserted in the upper DBR structure 30 may have the advantage of adjusting optical intensity distribution. From a computer model simulation that was conducted on the VCSEL device in FIGS. 10A to 10D, it was observed that the optical intensity distribution changes dramatically, and a peak optical intensity is pulled to a region between the two locations of phase shifts of high refractive index. This means that the interaction between the high optical intensity light emitted by the VCSEL device and structures around the resonator cavity 20 may be reduced.

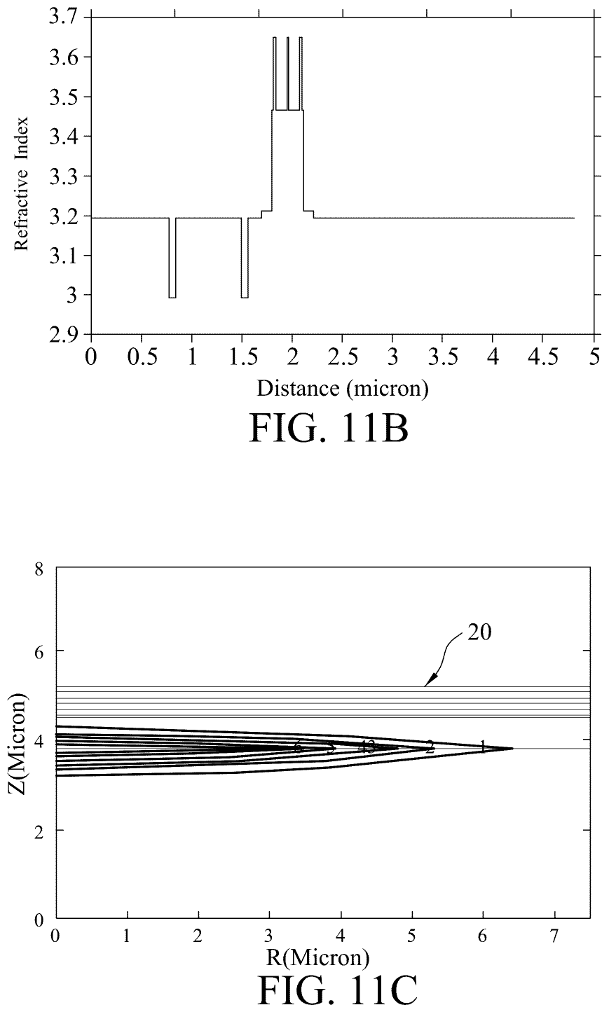

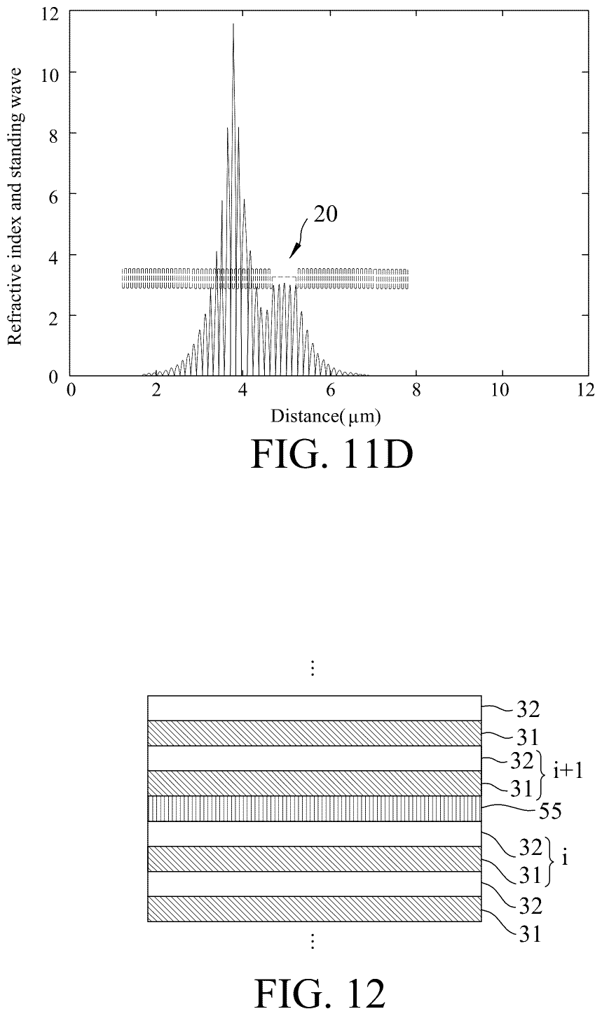

Referring to FIG. 9B and FIGS. 11A to 11D, two optical phase shift layers each with a thickness of 1/4λ and a high refractive index are inserted between two adjacent DBR pairs of the lower DBR structure 10. FIG. 11A is a power over current diagram showing relation between input current and output power of the VCSEL device. FIG. 11B is a refractive index over distance diagram showing the refractive indices at or near the resonator cavity 20, wherein two downward recesses indicate the locations of phase shifts of low refractive index. FIG. 11C is an optical intensity distribution cross-section diagram. It is noted that multiple middle dense horizontal lines are offset from the structure of the resonator cavity 20. FIG. 11D is an optical intensity distribution diagram of the interior of the VCSEL device. The two optical phase shift layer with the low refractive index inserted in the upper DBR structure 30 may have the advantage of adjusting optical intensity distribution.

From the embodiments above, it is apparent that by inserting two optical phase shift layers in the upper DBR structure 30 or the lower DBR structure the objectives of the disclosure may be achieved. In addition to the above, more than two optical phase shift layers may be inserted in the upper DBR structure 30 or the lower DBR structure 10 according to practical requirements. For example, in some embodiments, multiple optical phase shift layers may be inserted. Furthermore, the amount of segregation between two optical phase shift layers may be one DBR pairs or multiple DBR pairs. For example, in some embodiments, the amount of segregation between two optical phase shift layers may be 2, 3, 4, or 6. In addition, the placement of the optical phase shift layers in the upper DBR structure 30 or the lower DBR structure 10 may be adjusted and is not thus limited.

Referring to FIG. 12, a third embodiment of the VCSEL device according to the present disclosure is similar to the first embodiment. However, the difference is that in the third embodiment, a single one optical phase shift layer 55 is inserted between DBR pairs of the upper DBR structure 30. The DBR pairs are composed of alternating layers of the first material layer 31 with the low refractive index and the second material layer 32 with the high refractive index. More specifically, the optical phase shift layer 55 is inserted between the i^{th} DBR pair and the (i+1)^{th} DBR pair. The optical phase shift layer 55 has a refractive index that may be the same as that of the first material layer 31 or the second material layer 32. The optical phase shift layer has a thickness of (2Nλ/4)+(1/4×Kλ), where N is a positive integer, K ranges from 0.8 to 1.2, and λ is a wavelength of a light emitted by the VCSEL device which is equal to a physical thickness of the material layer required for a wave period of the wavelength of light emitted by the VCSEL device to advance. It is noted that i is a positive integer and i>1. In comparison to VCSEL devices that do not have an optical phase shift layer inserted in the upper DRB structure 30 and therefore has an optical intensity distribution positioned at the center of the resonator cavity 20, by inserting the optical phase shift layer 55 that may have a thickness of 1/4λ or 3/4λ between DBR pairs of the upper DBR structure 30, the peak optical intensity of the VCSEL device may be shifted to be outside of the resonator cavity, and thereby allow light emitted by the VCSEL device to have less beam divergence.

Additionally it should be noted that in some embodiments, the upper DBR structure 30 may be a normal DBR structure, and a first material layer 11 or a second material layer 12 may be inserted in the lower DBR structure to act as an optical phase shift layer with a thickness of (2Nλ/4)+(1/4×Kλ) and the effect of lowering beam divergence may also be achieved.

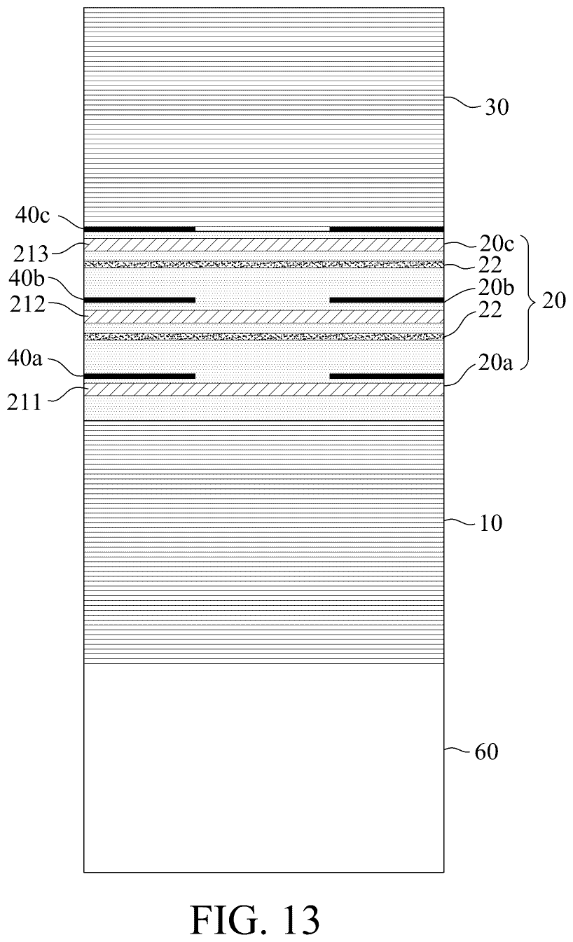

Referring to FIG. 13, a fourth embodiment of the VCSEL device according to the present disclosure is similar to the first embodiment and includes a substrate 60, a lower DBR structure 10 disposed on the substrate 60, a resonator cavity 20 located above the lower DBR structure 10, and an upper DBR structure disposed on the resonator cavity 20. The resonator cavity 20 includes at least one active layer. Referring to FIG. 13, in the fourth embodiment, the resonator cavity 20 includes a first active layer 20a, a second active layer 20b, and a third active layer 20c. The first, second, and third active layers 20a, 20b, 20c respectively may have at least one quantum well. In the fourth embodiment, the first active layer 20a has a first quantum well 211, the second active layer 20b has a second quantum well 212, and the third active layer 20c has a third quantum well 213. A tunnel junction 22 is located between the first active layer 20a and the second active layer 20b, and another tunnel junction 22 is between the second active layer 20b and the third active layer 20c. Each of the first active layer 20a, the second active layer 20b, and the third active layer 20c has at most one current confinement layer. In this embodiment, the first active layer 20a has a first current confinement layer 40a, the second active layer 20b has a second current confinement layer 40b, and the third active layer 20c has a third current confinement layer 40c. The lower DBR structure 10 and the upper DBR structure may be configured similarly to the corresponding components in the first to third embodiments of the disclosure. Additionally, it should be noted that in some embodiments there may be only one current confinement layer in the resonator cavity 20. For example, the current confinement layer may be in the resonator cavity 20 at a position close to the upper DBR structure 30. The amount of active layers may be adjusted according to required optical characteristics, and each of the active layers may have multiple quantum wells.

In summary of the above, in the VCSEL device according to the present disclosure, optical phase shift layers may be inserted in the upper or lower DBR structures 30, 10, which may control the optical intensity of the light emitted by the VCSEL device.

In the embodiments of the present disclosure, it is noted that the thickness of the optical phase shift layer is given by (2Nλ/4)+(1/4×Kλ) where N and K may take different values. A few examples of thickness values of the optical phase shift layers that are optimized by varying values of N and K are given below.

| N | Thickness = (2Nλ/4) + (¼ × Kλ) | Thickness examples |
|---|---|---|
| N = 0 | 0.2λ to 03λ | 0.25λ |
| N = 1 | 0.7λ to 0.8λ | 0.75λ |
| N = 2 | 1.2λ to 1.3λ | 1.25λ |
| N = 3 | 1.7λ to 1.8λ | 1.75λ |
| N = 4 | 2.2λ to 2.3λ | 2.25λ |
| N = 5 | 2.7λ to 2.8λ | 2.75λ |

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A (vertical-cavity surface-emitting laser) VCSEL device comprising:
a resonator cavity;
an upper distributed Bragg reflector (DBR) structure located on one side of said resonator cavity; and
a lower DBR structure located on an opposite side of said resonator cavity;
wherein each of said upper DBR structure and said lower DBR structure has a plurality of DBR pairs that are each formed from a stack of a first material layer with a low refractive index and a second material layer with a high refractive index;
wherein one of said upper DBR structure and said lower DBR structure has at least one optical phase shift layer inserted between two adjacent ones of said DBR pairs, said at least one optical phase shift layer having a thickness of (2Nλ/4)+(1/4×Kλ), where N is a positive integer, K ranges from 0.8 to 1.2, and λ is a wavelength of a light emitted by said VCSEL device;
wherein said first material layer has a refractive index of η₁, said second material layer has a refractive index of η₂, and said at least one optical phase shift layer has a refractive index of η, and 0.8η₁≤η≤1.2η₁ or 0.8η₂≤η≤1.2η₂.

2. The VCSEL device as claimed in claim 1, wherein N≤5.

3. The VCSEL device as claimed in claim 1, wherein a peak optical intensity of said one of said upper and lower DBR structures, which has said two adjacent ones of said DBR pairs inserted with said at least one optical phase shift layer, is higher than a peak optical intensity of said resonator cavity.

4. The VCSEL device as claimed in claim 1, wherein the at least one optical phase shift layer in said one of said upper DBR structure and said lower DBR structures includes at least two optical phase shift layers which are spaced apart from each other by one or more than one of said DBR pairs.

5. The VCSEL device as claimed in claim 4, wherein said at least two optical phase shift layers are separated by no more than 10 of said DBR pairs of said one of said upper DBR structure and said lower DBR structure.

6. The VCSEL device as claimed in claim 1, wherein said stack of said first and second materials is AlₓGa₁₋ₓAs/Al_{y}Ga_{1-y}As, AlInN/GaN, SiO₂/Nb₂O₅, AlGalnAs/InP, or SiO₂/Ta₂O₅, where 1>x>y>0.

7. The VCSEL device as claimed in claim 1, further comprising a substrate disposed at one side of said lower DBR structure opposite to said resonator cavity.

8. The VCSEL device as claimed in claim 1, wherein:
said VCSEL device has a light exiting surface on a side of said upper DBR structure that is remote from said resonator cavity; and
a reflectance of said lower DBR structure is higher than a reflectance of said upper DBR structure.

9. The VCSEL device as claimed in claim 1, wherein said at least one optical phase shift layer is made of a same material as said first material layer, and said first material layer of one of said two adjacent ones of said DBR pairs has an increased thickness that is increased by an amount that is equal to the thickness of (2Nλ/4)+(1/4×Kλ) of said at least one optical phase shift layer.

10. The VCSEL device as claimed in claim 1, wherein said at least one optical phase shift layer is made of a same material as said second material layer, and said second material layer of one of said two adjacent ones of said DBR pairs has an increased thickness that is increased by an amount equal to the thickness of (2Nλ/4)+(1/4×Kλ) of said at least one optical phase shift layer.

11. A method of making the VCSEL device comprising the steps of:
a) epitaxially forming a lower DBR structure, a resonator cavity, and an upper DBR structure sequentially so that the upper DBR structure and the lower DBR structure are formed on opposite sides of the resonator cavity, wherein each of the upper DBR structure and the lower DBR structure has a plurality of DBR pairs that are each epitaxially formed by alternatingly growing a first material layer with a low refractive index and a second material layer with a high refractive index repeatedly;
b) forming a current confinement layer in proximity to the resonator cavity or inside the resonator cavity;
c) inserting at least one optical phase shift layer in at least one of the upper DBR structure and the lower DBR structure to adjust a peak optical intensity of the VCSEL device to shift outside of the resonator cavity, wherein the at least one optical phase shift layer has a thickness of (2Nλ/4)+(1/4×Kλ), where N is a positive integer, K ranges from 0.8 to 1.2, and λ is a wavelength of a light emitted by said VCSEL device, wherein the first material layer has a refractive index of η₁, the second material layer has a refractive index of η₂, and the at least one optical phase shift layer has a refractive index of η, and 0.8η₁≤η≤1.2η₁ or 0.8η₂≤η≤1.2η₂.

12. The method of making the VCSEL device as claimed in claim 11, wherein in the step of epitaxially forming the upper DBR structure and the second DRB structure, a growth thickness of the first material layer or the second material layer is increased to form the at least one optical phase shift layer.

13. The method of making the VCSEL device as claimed in claim 11, wherein the first and second materials is AlₓGa₁₋ₓAs/Al_{y}Ga_{1-y}As, AlInN/GaN, SiO₂/Nb₂O₅, AlGalnAs/InP, or SiO₂/Ta₂O₅, where 1>x>y>0.

14. The method of making the VCSEL device as claimed in claim 11, wherein N≤5.

15. The method of making the VCSEL device as claimed in claim 11, wherein N≤5.

16. The method of making the VCSEL device as claimed in claim 11, wherein the at least one optical phase shift layer in the one of the upper DBR structure and the lower DBR structures includes at least two optical phase shift layers which are spaced apart from each other by one or more than one of the DBR pairs.

17. The method of making the VCSEL device as claimed in claim 16, wherein the at least two optical phase shift layers are separated by no more than 10 of the DBR pairs of the one of said upper DBR structure and the lower DBR structure.

18. A VCSEL chip comprising a plurality of the VCSEL devices as claimed in claim 1 that are arranged in an array or randomly distributed on the VCSEL chip.

19. A lidar system comprising at least one VCSEL chip as claimed in claim 11.

20. A lidar system comprising at least one VCSEL device as claimed in claim 1.
